(19) United States
(12) Patent Application Publication
(10) Pub. No.: US 2024/0219834 A1
(43) Pub. Date: Jul. 4, 2024

(54) METHOD FOR FORMING A RESIST PATTERN

(71) Applicant: NISSAN CHEMICAL CORPORATION, Tokyo (JP)

(72) Inventors: Shun KUBODERA, Toyama-shi (JP); Takahiro KISHIOKA, Toyama-shi (JP); Tokio NISHITA, Toyama-shi (JP)

(73) Assignee: NISSAN CHEMICAL CORPORATION, Tokyo (JP)

(21) Appl. No.: 18/286,612

(22) PCT Filed: Apr. 25, 2022
(86) PCT No.: PCT/JP2022/018653

§ 371 Date: Oct. 12, 2023

(30) Foreign Application Priority Data
Apr. 26, 2021 (JP) 2021-074152

(51) Int. Cl. G03F 7/11; G03F 7/031; G03F 7/16

(52) U.S. Cl. CPC G03F 7/11; G03F 7/031; G03F 7/168

(57) ABSTRACT

A semiconductor device manufacturing process, forming a multilayer structure of a metal oxide (e.g., copper oxide) and a resist underlayer film on a stepped metal substrate reduces exposure reflectance from the substrate, thereby reducing standing waves of the resist pattern (defects caused by reflection) and provides a favorable rectangular resist pattern on the substrate. A pattern-equipped substrate manufacturing method includes: a step for performing an oxidation treatment on a substrate containing metal on a surface thereof to form a metal oxide film on the substrate surface; a step for applying a resist on the metal oxide film and conducting baking to form a resist film; a step for exposing a semiconductor substrate covered by the metal oxide film and the resist; and a step for developing the exposed resist film and conducting patterning.

### FIELD OF THE INVENTION

The present invention relates to a method for forming a resist pattern, a method for producing a substrate having a resist pattern, a method for producing a semiconductor device, and a method for reducing standing waves of a resist pattern.

### BACKGROUND ART

A lithography process in the production of a semiconductor has been widely known, in which a resist underlayer film is formed between a substrate and a resist film formed on the substrate, forming a resist pattern having a desired form. In recent years, the so-called wiring step (post-step) is being scaled-down, and a metal substrate, such as copper, is processed by a lithography process.

Patent Literature 1 discloses a resist pattern and a method for producing a conductor pattern.

### CITATION LIST

### Patent Literature

Patent Literature 1: JP 2006-154570 A

### SUMMARY OF INVENTION

### Technical Problem

In the production process for a semiconductor device, when using a resist underlayer film on a stepped metal (for example, copper) substrate, the resist underlayer film is required to have high film thickness uniformity (conformal properties) for reducing a burden of etching. The resist underlayer film is improved in the film thickness uniformity (conformal properties) by reducing the thickness of the film, but a problem arises in that reflection from the substrate cannot be satisfactorily suppressed, so that standing waves is caused in the resist pattern formed as an upper layer on the resist underlayer film.

### Solution to Problem

The present invention encompasses the followings.

[1] A method for producing a substrate having a resist pattern, comprising the steps of:

subjecting a substrate having a metal on a surface thereof to oxidation treatment to form a metal oxide film (or a film of an oxide of the metal) on the surface of the substrate;

applying a resist onto the metal oxide film and baking the applied resist to form a resist film;

exposing the substrate, preferably a semiconductor substrate, covered with the metal oxide film and the resist; and

subjecting the exposed resist film to development and patterning.

[2] A method for producing a substrate having a resist pattern, comprising the steps of:

applying a resist underlayer film-forming composition to a substrate having a metal on a surface thereof, and then heating the applied composition in the presence of oxygen to form a stacked film having a resist underlayer film present on a metal oxide film (or a stacked material having a film of an oxide of the metal on the substrate and a resist underlayer film on the oxide film);

applying a resist onto the resist underlayer film and baking the applied resist to form a resist film;

exposing the substrate, preferably a semiconductor substrate, covered with the resist underlayer film and the resist; and

subjecting the exposed resist film to development and patterning.

[3] The method for producing a substrate having a resist pattern according to [1] or [2], wherein the resist pattern has reduced standing waves.

[4] The method for producing a substrate having a resist pattern according to [1], wherein the oxidation treatment is selected from a heating treatment in the presence of oxygen, an oxygen plasma treatment, an ozone treatment, a hydrogen peroxide treatment, and an oxidizing agent-containing alkaline chemical liquid treatment.

[5] The method for producing a substrate having a resist pattern according to [1] or [2], wherein the metal comprises copper.

[6] The method for producing a substrate having a resist pattern according to [2], wherein the resist underlayer film comprises a heterocyclic compound.

[7] The method for producing a substrate having a resist pattern according to any one of [2] to [6], wherein the resist underlayer film comprises a compound represented by the following formula (I):

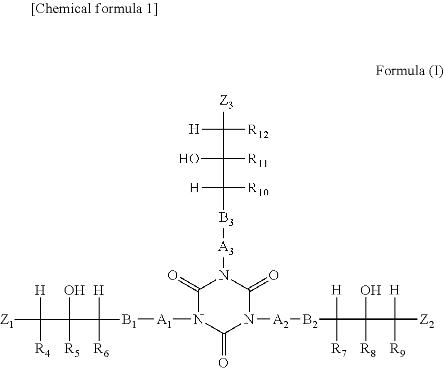

wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula II):

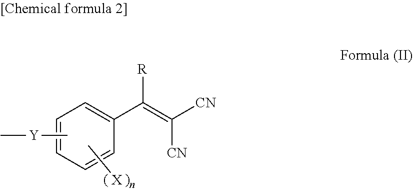

wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

[8] A method for producing a semiconductor device, comprising the steps of:

subjecting a semiconductor substrate having a metal on a surface thereof to oxidation treatment to form a metal oxide film (or a film of an oxide of the metal) on the surface of the substrate;

applying a resist onto the metal oxide film and baking the applied resist to form a resist film;

exposing the semiconductor substrate covered with the metal oxide film and the resist; and

subjecting the exposed resist film to development and patterning.

[9] A method for producing a semiconductor device, comprising the steps of:

applying a resist underlayer film-forming composition to a semiconductor substrate having a metal on a surface thereof, and then heating the applied composition in the presence of oxygen to form a stacked film having a resist underlayer film present on a metal oxide film (or a stacked material having a film of an oxide of the metal on the substrate and a resist underlayer film on the oxide film);

applying a resist onto the resist underlayer film and baking the applied resist to form a resist film;

exposing the semiconductor substrate covered with the resist underlayer film and the resist; and

subjecting the exposed resist film to development and patterning.

[10] A method for reducing standing waves of a resist pattern, comprising the steps of:

subjecting a substrate, preferably semiconductor substrate, having a metal on a surface thereof to oxidation treatment to form a metal oxide film (or a film of an oxide of the metal) on the surface of the substrate;

applying a resist onto the metal oxide film and baking the applied resist to form a resist film;

exposing the substrate, preferably a semiconductor substrate, covered with the metal oxide film and the resist; and

subjecting the exposed resist film to development and patterning.

[11] A method for reducing standing waves of a resist pattern, comprising the steps of:

applying a resist underlayer film-forming composition to a substrate, preferably semiconductor substrate, having a metal on a surface thereof, and then heating the applied composition in the presence of oxygen to form a stacked film having a resist underlayer film present on a metal oxide film (or a stacked material having a film of an oxide of the metal on the substrate and a resist underlayer film on the oxide film);

applying a resist onto the resist underlayer film and baking the applied resist to form a resist film;

exposing the substrate, preferably a semiconductor substrate, covered with the resist underlayer film and the resist; and

subjecting the exposed resist film to development and patterning.

### Advantageous Effects of Invention

A metal oxide film (for example, a copper oxide film) has a high n/k (refractive index/absorption coefficient) value with respect to, for example, an i-line (365 nm). In a lithography process for the production of a semiconductor device, when a metal oxide film (for example, copper oxide) is preliminarily formed on the surface of a semiconductor substrate, or a stacked structure of a metal oxide film (for example, copper oxide) and a resist underlayer film is formed, the exposure reflectance from a substrate can be reduced, so that standing waves of a resist pattern (problem due to reflection) is reduced, making it possible to obtain a resist pattern having an excellent rectangular form on a substrate (for example, a copper substrate). By applying the above-mentioned method, a substrate having a resist pattern having excellent form can be produced, and a semiconductor device can be produced using the resist pattern. Further, there can also be provided a method for reducing the problem of a resist pattern (standing wave) in a lithography process for a semiconductor device.

### DESCRIPTION OF EMBODIMENTS

### <Method for Producing a Substrate Having a Resist Pattern>

The method for producing a substrate having a resist pattern of the present invention is a method for producing a substrate having a resist pattern, comprising the steps of:

subjecting a substrate having a metal on a surface thereof to oxidation treatment to form a metal oxide film on the surface of the substrate;

applying a resist onto the metal oxide film and baking the applied resist to form a resist film;

exposing the substrate, preferably a semiconductor substrate, covered with the metal oxide film and the resist; and

subjecting the exposed resist film to development and patterning.

The method for producing a substrate having a resist pattern of the present invention may comprise the steps of:

applying a resist underlayer film-forming composition to a substrate having a metal on a surface thereof, and then heating the applied composition in the presence of oxygen to form a stacked film having a resist underlayer film present on a metal oxide film;

applying a resist onto the resist underlayer film and baking the applied resist to form a resist film;

exposing the substrate, preferably a semiconductor substrate, covered with the resist underlayer film and the resist to exposure; and

subjecting the exposed resist film to development and patterning.

The standing waves of the resist pattern may be reduced. A reduction of the standing waves (waviness) may be found from the fact that the standing waves of the resist pattern produced by the method of the present invention is considerably reduced, as compared to that in the case where a metal oxide film is not formed on the surface of the substrate.

For reducing the standing waves, it is necessary to reduce the “standing wave ratio S” which is an index for quantitating the standing waves, and which is represented by the expression below and, for example, described in JP 2000-506288 A. For example, with respect to the resist film for forming the resist pattern in the present invention, or optionally a stacked film of the resist film and, for example, the resist underlayer film, metal oxide film, and substrate, it is necessary that the result of calculation of the reflectance be 20% or less, preferably 15% or less, preferably 10% or less, preferably 7% or less, preferably 6% or less.

S=4\sqrt{RₜR^{b}} exp(−αD/cos θᵣ) [Expression 1]

In the above expression, S is standing wave ratio, Rt is an interfacial reflectance between the resist and the air, Rb is an interfacial reflectance between the resist and the substrate, α is an absorption coefficient of the resist with respect to the wavelength of the light source of exposure, D is a thickness of the resist film, and an angle θi of incidence of the light for exposure and an angle θr of refraction satisfy the relationship: sin θi/sin θr=nₐᵢᵣ/nᵣₑₛᵢₛₜ (wherein nₐᵢᵣ and nᵣₑₛᵢₛₜ are, respectively, refractive indexes of the air and the resist) (reference document: T. Brunner, Proc. SPIE1466, 297 (1991)).

### <Metal>

With respect to the metal in the present invention, there is no particular limitation as long as it is a metal which is used in the production of a semiconductor device as, for example, a wiring material. Specific examples include iron, copper, tin, and aluminum, but particularly, copper and aluminum are preferred, and copper is especially preferred.

### <Oxidation Treatment>

With respect to the oxidation treatment in the present invention, there is no particular limitation as long as it is a method of forming a metal oxide having a certain thickness on the metal substrate, but the oxidation treatment may be selected from a heating treatment in the presence of oxygen, an oxygen plasma treatment, an ozone treatment, a hydrogen peroxide treatment, and an oxidizing agent-containing alkaline chemical liquid treatment.

### <Thickness and n/k (Refractive Index/Absorption Coefficient)>

### (Thickness)

The thickness of the metal oxide film in the present invention may be controlled to have an appropriate thickness from the n/k (refractive index/absorption coefficient) value for the wavelength for exposure by, for example, the known reflectance simulation described in JP 2000-506288 A, but is, for example, within the range of 1 to 100 nm. Accordingly, the preferred range of the thickness of the resist underlayer film/metal oxide film in the present invention is within the range of (5 to 300 nm)/(1 to 100 nm).

### (n/k (Refractive Index/Absorption Coefficient))

For example, when the wavelength for exposure is 365 nm, the n/k values of the metal oxide film and resist underlayer film used in the present invention are values in the following respective ranges.

Metal oxide film: n=1.0 to 4.0, k=0.1 to 2.0

Resist underlayer film: n=1.5 to 2.0, k=0.1 to 0.6

### <Resist Underlayer Film>

With respect to the resist underlayer film in the present invention, there is no particular limitation as long as it is a resist underlayer film, which is disposed under the resist in a lithography process for the production of a semiconductor device, and which exhibits the advantageous effects of the present invention, but the resist underlayer film may comprise a known organic compound, and may comprise a known heterocyclic compound.

Alternatively, the resist underlayer film may comprise a known organic polymer or inorganic polymer.

The resist underlayer film described in the present invention may be produced by applying a known resist underlayer film-forming composition to a substrate and baking the applied composition.

For example, the resist underlayer film may be a resist underlayer film comprising the heterocyclic compound having a dicyanostyryl group described in WO 2020/255984.

For example, the resist underlayer film may comprise a compound represented by the following formula (I):

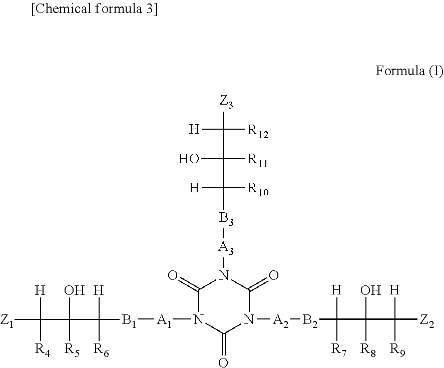

wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II):

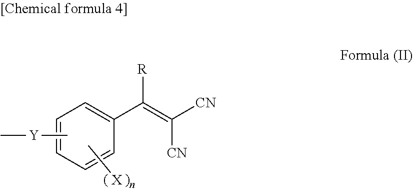

wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

Examples of the alkyl groups include optionally substituted, linear or branched alkyl groups, and examples of such alkyl groups include a methyl group, an ethyl group, a n-propyl group, an isopropyl group, a n-butyl group, a sec-butyl group, a tert-butyl group, a n-pentyl group, an isopentyl group, a neopentyl group, a n-hexyl group, an isohexyl group, a n-heptyl group, a n-octyl group, a cyclohexyl group, a 2-ethylhexyl group, a n-nonyl group, an isononyl group, a p-tert-butylcyclohexyl group, a n-decyl group, a n-dodecylnonyl group, an undecyl group, a dodecyl group, a tridecyl group, a tetradecyl group, a pentadecyl group, a hexadecyl group, a heptadecyl group, an octadecyl group, a nonadecyl group, and an eicosyl group. Preferred is an alkyl group having 1 to 20 carbon atoms, more preferred is an alkyl group having 1 to 12 carbon atoms, further preferred is an alkyl group having 1 to 8 carbon atoms, and most preferred is an alkyl group having 1 to 4 carbon atoms.

Examples of the alkoxy groups include groups corresponding to the above-mentioned alkyl groups having an oxygen atom bonded thereto. Examples of such groups include a methoxy group, an ethoxy group, a propoxy group, and a butoxy group.

Examples of the alkoxycarbonyl groups include groups corresponding to the above-mentioned alkyl groups having an oxygen atom and a carbonyl group bonded thereto. Examples of such groups include a methoxycarbonyl group, an ethoxycarbonyl group, a propoxycarbonyl group, and a butoxycarbonyl group.

Examples of the alkylene groups include divalent groups obtained by further removing a hydrogen atom from the above-mentioned alkyl group. Examples of such groups include a methylene group, an ethylene group, a 1,3-propylene group, and a 1,2-propylene group.

Examples of the arylene groups include a phenylene group, an o-methylphenylene group, a m-methylphenylene group, a p-methylphenylene group, an α-naphthylene group, a β-naphthylene group, an o-biphenylylene group, a m-biphenylylene group, a p-biphenylylene group, a 1-anthrylene group, a 2-anthrylene group, a 9-anthrylene group, a 1-phenanthrylene group, a 2-phenanthrylene group, a 3-phenanthrylene group, a 4-phenanthrylene group, and a 9-phenanthrylene group. Preferred is an arylene group having 6 to 14 carbon atoms, and more preferred is an arylene group having 6 to 10 carbon atoms.

The halogen atom generally indicates atoms of fluorine, chlorine, bromine, and iodine.

The ester linkage in the present invention includes —COO— and —OCO—.

The entire disclosure of WO 2020/255984 is incorporated herein by reference.

The resist underlayer film in the present invention may comprise the polymer having a repeating unit structure, which is described in WO 2013/018802, and represented by the following formula (1):

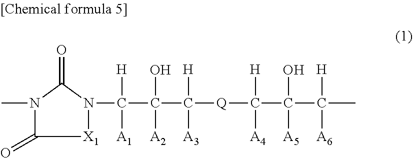

wherein each of A₁, A₂, A₃, A₄, A₅, and A₆ represents a hydrogen atom, a methyl group, or an ethyl group; X₁ represents the following formula (2), (3), (4), or (0):

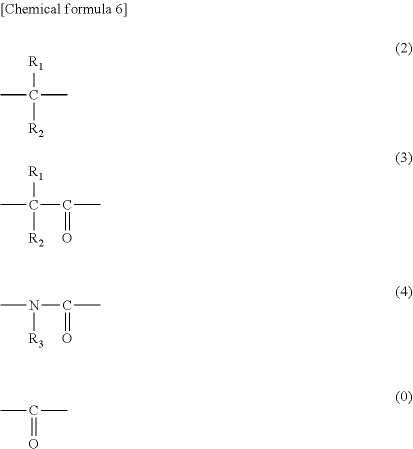

wherein each of R₁ and R₂ represents a hydrogen atom, a halogen atom, an alkyl group having 1 to 6 carbon atoms, an alkenyl group having 3 to 6 carbon atoms, a benzyl group, or a phenyl group, wherein the alkyl group having 1 to 6 carbon atoms, alkenyl group having 3 to 6 carbon atoms, benzyl group, and phenyl group are optionally substituted with a group selected from the group consisting of an alkyl group having 1 to 6 carbon atoms, a halogen atom, an alkoxy group having 1 to 6 carbon atoms, a nitro group, a cyano group, a hydroxy group, a carboxyl group, and an alkylthio group having 1 to 6 carbon atoms, and wherein R₁ and R₂ are optionally bonded together to form a ring having 3 to 6 carbon atoms; and R₃ represents a halogen atom, an alkyl group having 1 to 6 carbon atoms, an alkenyl group having 3 to 6 carbon atoms, a benzyl group, or a phenyl group, wherein the phenyl group is optionally substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms,
and Q represents the following formula (5) or (6):

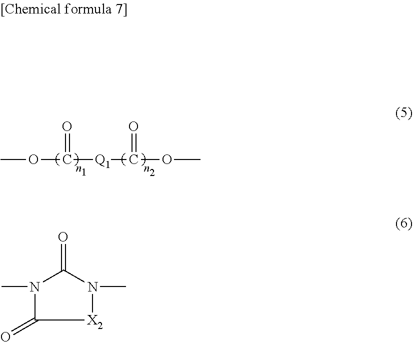

wherein Q₁ represents an alkylene group having 1 to 10 carbon atoms, a phenylene group, a naphthylene group, or an anthrylene group, wherein the alkylene group, phenylene group, naphthylene group, and anthrylene group are independently optionally substituted with an alkyl group having 1 to 6 carbon atoms, a carbonyloxyalkyl group having 2 to 7 carbon atoms, a halogen atom, an alkoxy group having 1 to 6 carbon atoms, a phenyl group, a nitro group, a cyano group, a hydroxy group, an alkylthio group having 1 to 6 carbon atoms, a group having a disulfide group, a carboxyl group, or a group comprising a combination of the above groups; each of n₁ and n₂ represents a number of 0 or 1; and X₂ represents the formula (2), (3), or (0).

The resist underlayer film in the present invention may be derived from the resist underlayer film-forming composition described in WO 2020/255985, the composition comprising a polymer (P) having a dicyanostyryl group or a compound (C) having a dicyanostyryl group,

comprising a solvent,

being free from an alkylated aminoplast crosslinking agent derived from melamine, urea, benzoguanamine, or glycoluril, and

being free from a protonic acid curing catalyst.

The resist underlayer film-forming composition in the present invention may be derived from the 1. improved ARC composition described in JP H11-511194 A, the composition comprising:
a. a dye-grafted hydroxy-functional oligomer reaction product of a preliminarily selected phenol- or carboxylic acid-functional dye and a poly(epoxide) resin having an epoxy functional value of more than 2.0 to less than 10, wherein the reaction product has light-absorption properties effective for ARC application to a base layer;
b. an alkylated aminoplast crosslinking agent derived from melamine, urea, benzoguanamine, or glycoluril;
c. a protonic acid curing catalyst; and
d. a solvent system containing a low or medium boiling-point alcohol, wherein, in the solvent system, the alcohol occupies at least 20% by weight of the total amount of the solvents contained, and the molar ratio of the alcohol to the equivalent methylol unit of aminoplast is at least 4:1,
   and having:
e. an ether or ester linkage derived from a poly(epoxide) molecule,
wherein the improved ARC prevents resist/ARC component intermixing by a heat curing effect of ARCs, provides an improved optical concentration in the target exposure and ARC layer thickness, and requires no high molecular-weight thermoplastic ARC binder exhibiting a high solubility difference.

The resist underlayer film in the present invention may be derived from the antireflection coating composition described in JP 2009-37245 A, which is used in a microlithographic process, wherein the composition comprises a polymer dispersed or dissolved in a solvent system, a crosslinking agent, a compound for light attenuation, and a strong acid,

wherein the polymer is selected from the group consisting of an acrylic polymer, a polyester, an epoxy novolak, a polysaccharide, a polyether, a polyimide, and a mixture thereof,

wherein the crosslinking agent is selected from the group consisting of an amino resin and an epoxy resin,

wherein the compound for light attenuation is selected from the group consisting of a phenolic compound, a carboxylic acid, phosphoric acid, a cyano compound, benzene, naphthalene, and anthracene, and

wherein the strong acid is contained in an amount of less than 1.0% by mass, based on the mass of the composition (100% by mass), and the strong acid is selected from the group consisting of p-toluenesulfonic acid, sulfuric acid, hydrochloric acid, hydrobromic acid, nitric acid, trifluoroacetic acid, and perchloric acid.

The entire disclosure of WO 2013/018802, WO 2020/255985, JP H11-511194 A, and JP 2009-37245 A is incorporated herein by reference.

Alternatively, the resist underlayer film may be a resist underlayer film comprising a compound represented by the following formula.

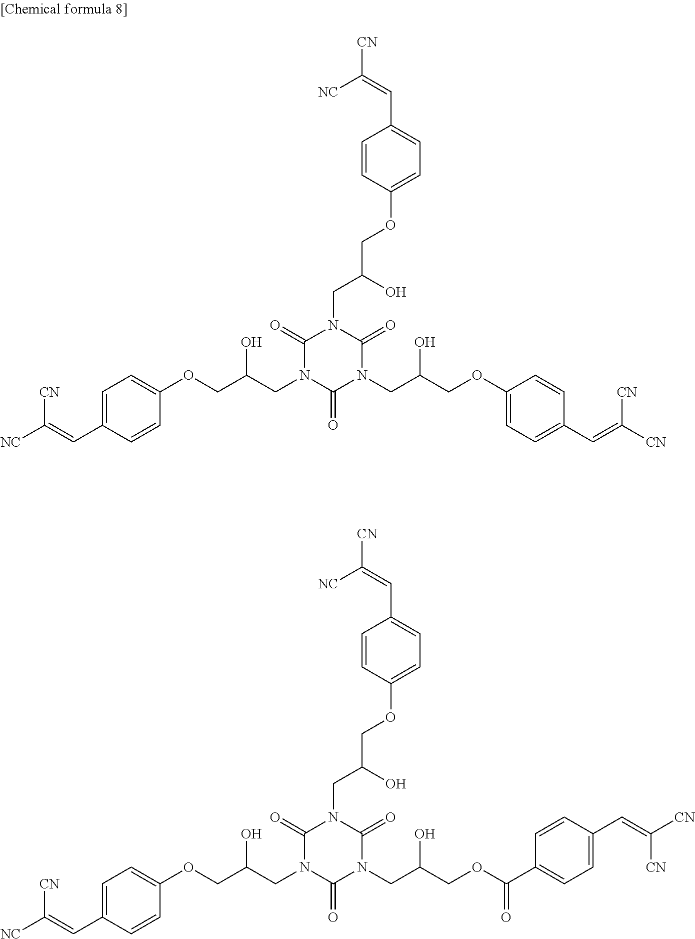 [SMILES: N#CC(C#N)=Cc1ccc(OCC(O)Cn2c(=O)n(CC(O)COc3ccc(C=C(C#N)C#N)cc3)c(=O)n(CC(O)COc3ccc(C=C(C#N)C#N)cc3)c2=O)cc1 ; N#CC(C#N)=Cc1ccc(OCC(O)Cn2c(=O)n(CC(O)COC(=O)c3ccc(C=C(C#N)C#N)cc3)c(=O)n(CC(O)COc3ccc(C=C(C#N)C#N)cc3)c2=O)cc1]

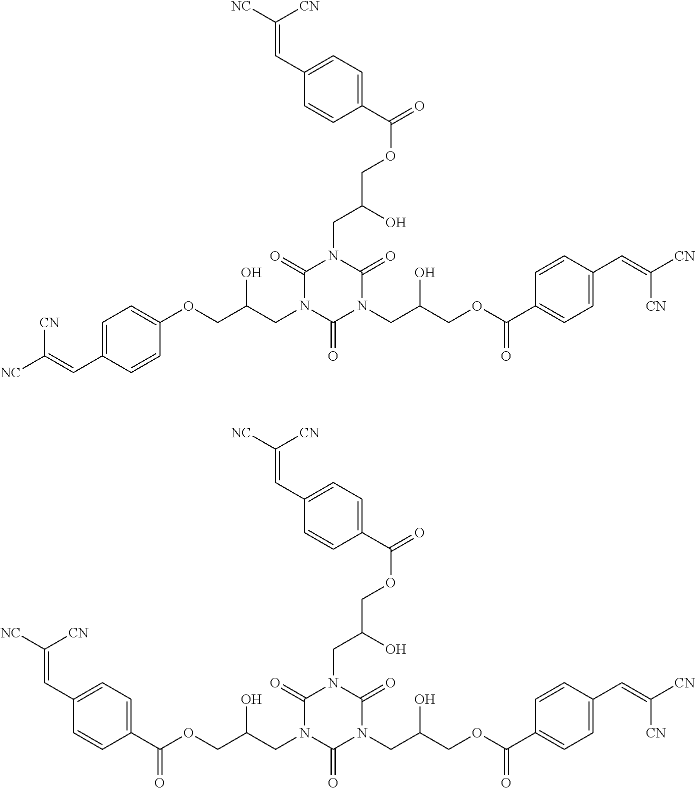 [SMILES: N#CC(C#N)=Cc1ccc(OCC(O)Cn2c(=O)n(CC(O)COC(=O)c3ccc(C=C(C#N)C#N)cc3)c(=O)n(CC(O)COC(=O)c3ccc(C=C(C#N)C#N)cc3)c2=O)cc1 ; N#CC(C#N)=Cc1ccc(C(=O)OCC(O)Cn2c(=O)n(CC(O)COC(=O)c3ccc(C=C(C#N)C#N)cc3)c(=O)n(CC(O)COC(=O)c3ccc(C=C(C#N)C#N)cc3)c2=O)cc1]

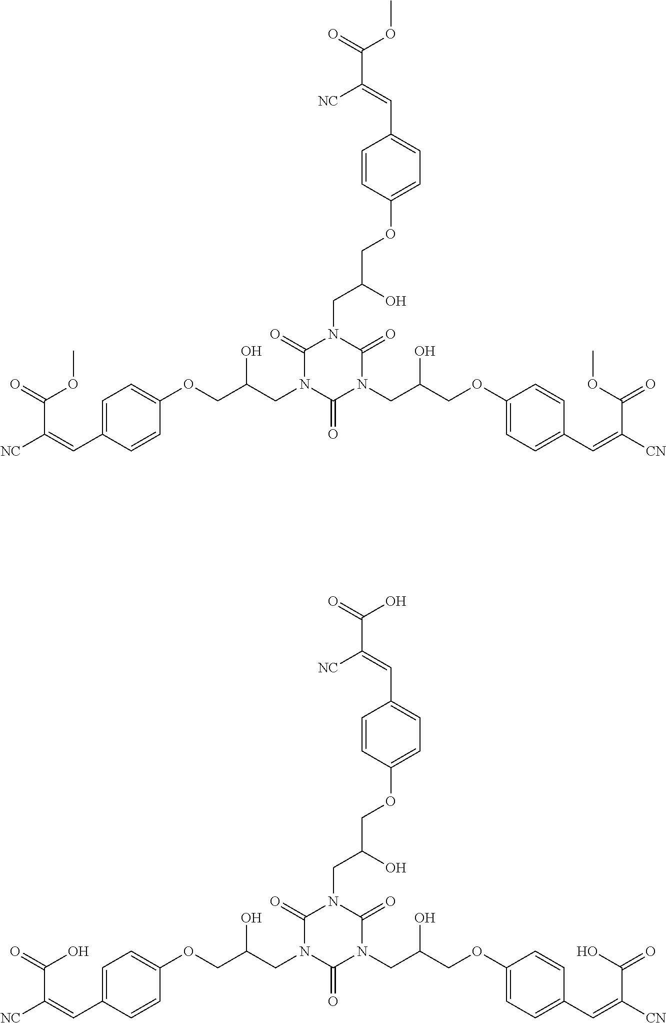 [SMILES: COC(=O)/C(C#N)=C\c1ccc(OCC(O)Cn2c(=O)n(CC(O)COc3ccc(/C=C(/C#N)C(=O)OC)cc3)c(=O)n(CC(O)COc3ccc(/C=C(\C#N)C(=O)OC)cc3)c2=O)cc1 ; N#C/C(=C/c1ccc(OCC(O)Cn2c(=O)n(CC(O)COc3ccc(/C=C(/C#N)C(=O)O)cc3)c(=O)n(CC(O)COc3ccc(/C=C(\C#N)C(=O)O)cc3)c2=O)cc1)C(=O)O]

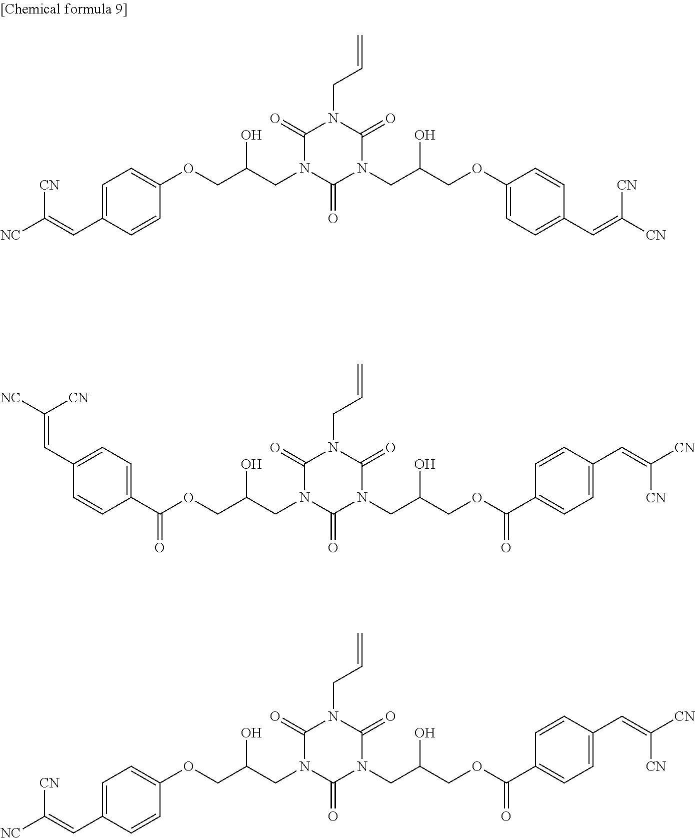 [SMILES: C=CCn1c(=O)n(CC(O)COc2ccc(C=C(C#N)C#N)cc2)c(=O)n(CC(O)COc2ccc(C=C(C#N)C#N)cc2)c1=O ; C=CCn1c(=O)n(CC(O)COC(=O)c2ccc(C=C(C#N)C#N)cc2)c(=O)n(CC(O)COC(=O)c2ccc(C=C(C#N)C#N)cc2)c1=O ; C=CCn1c(=O)n(CC(O)COC(=O)c2ccc(C=C(C#N)C#N)cc2)c(=O)n(CC(O)COc2ccc(C=C(C#N)C#N)cc2)c1=O]

The resist underlayer film may be a resist underlayer film comprising a polymer having a unit structure represented by the following formula.

In the following formulae, m, n, and 1 represent the number of repeating units or a molar ratio for copolymerization.

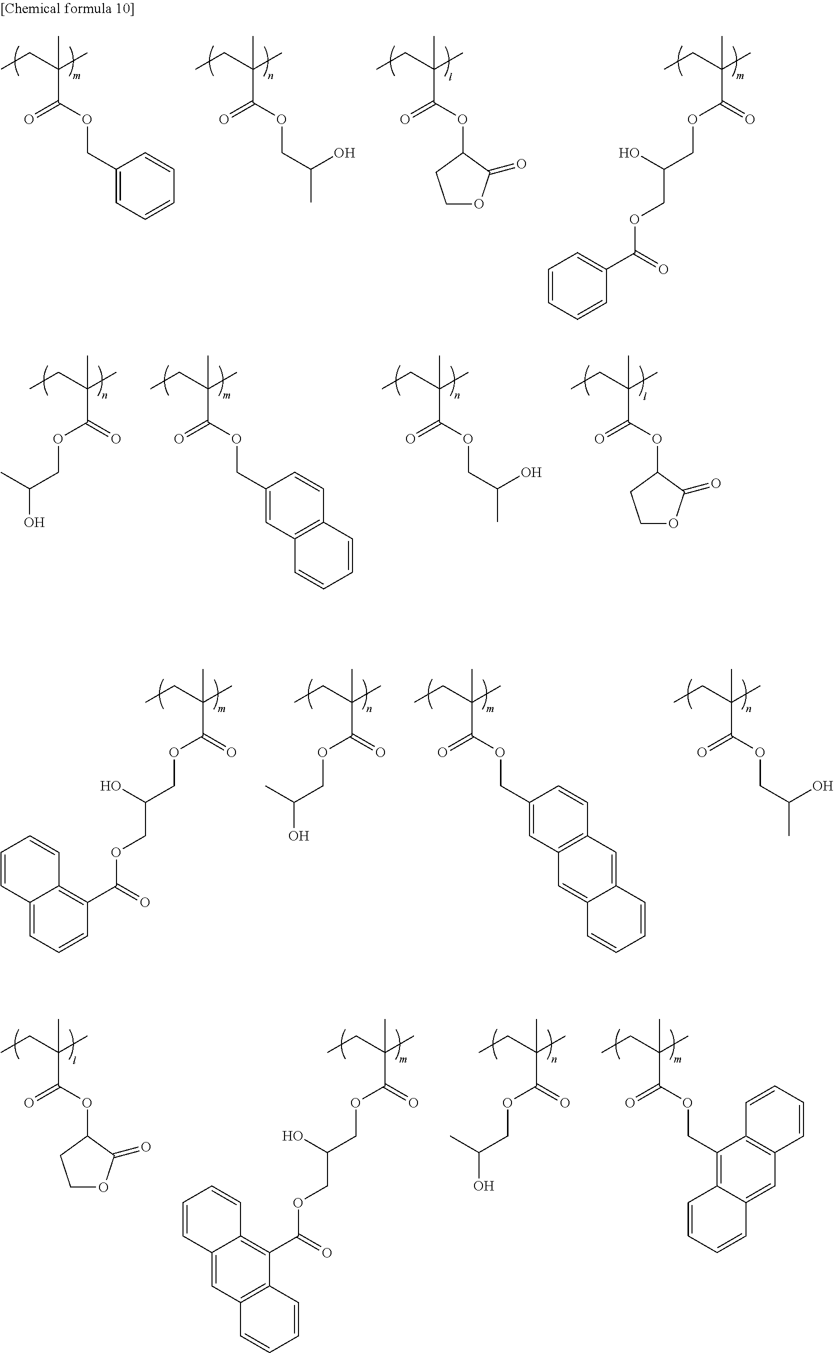

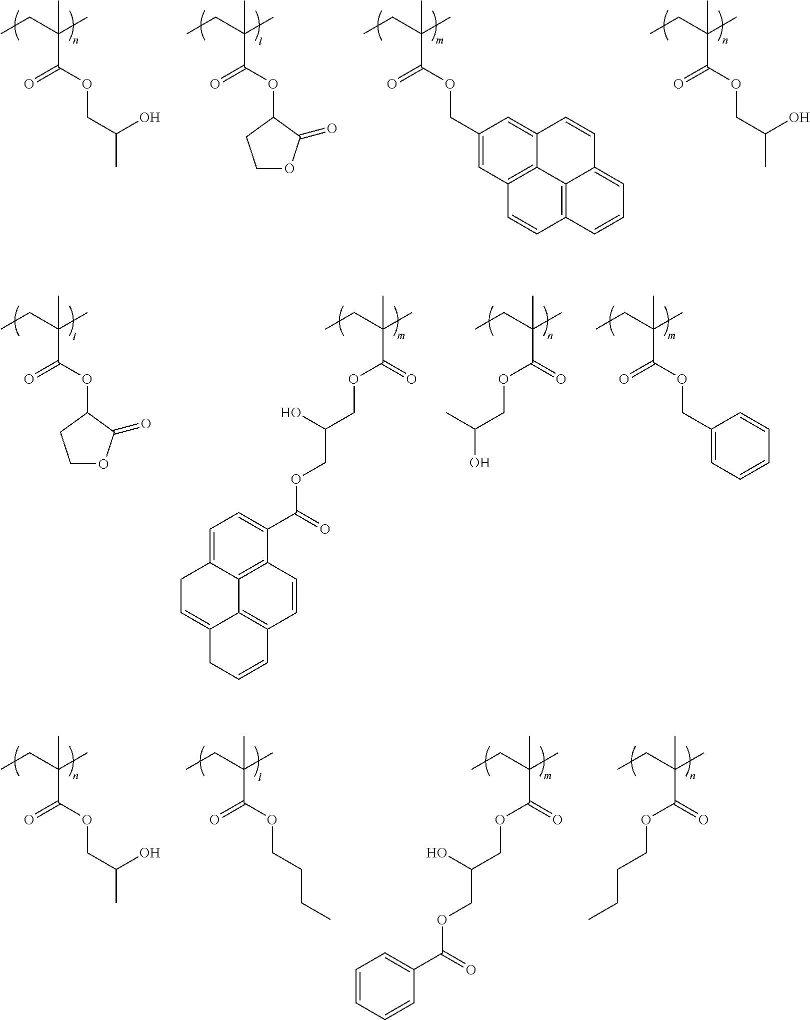

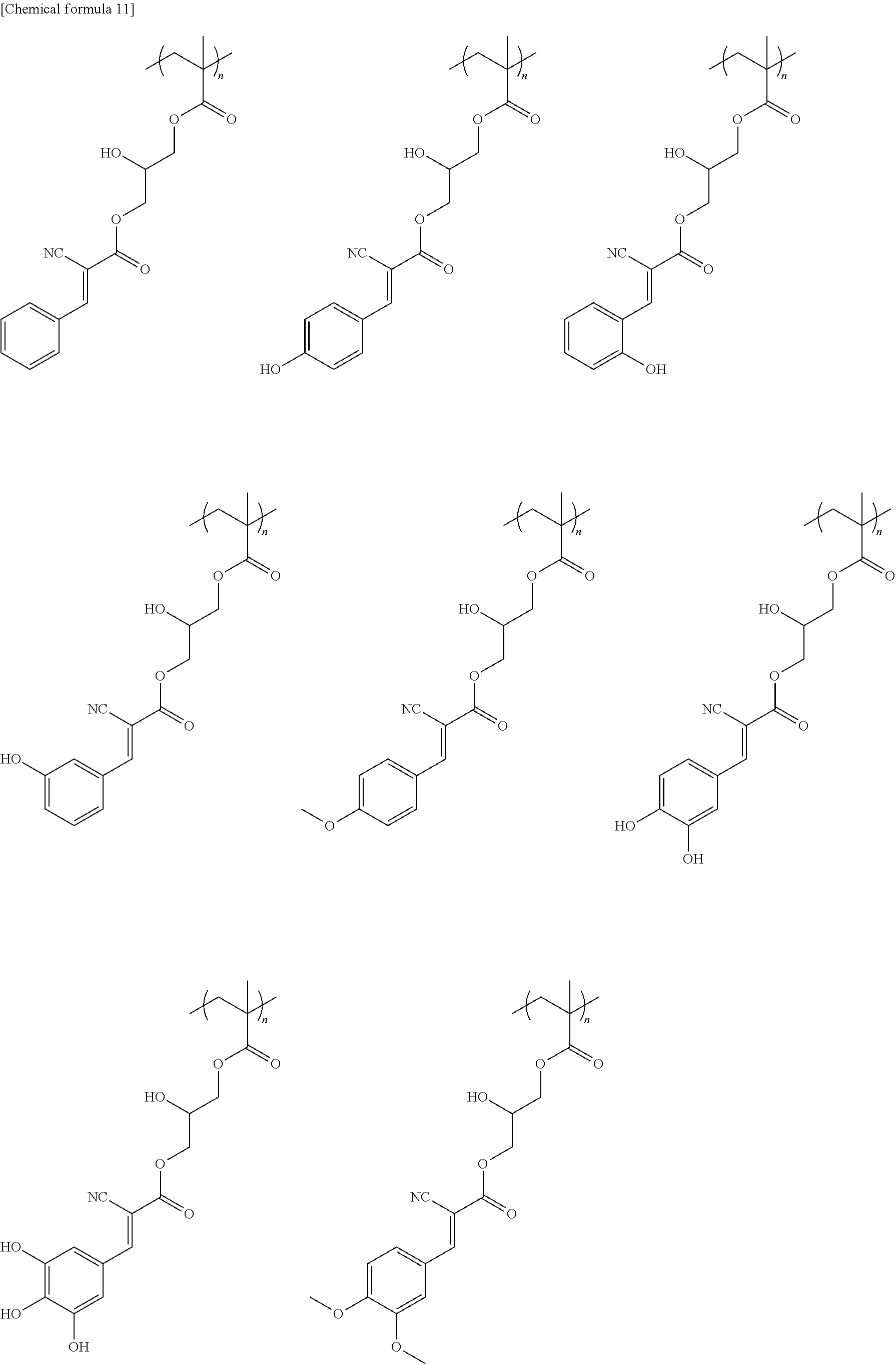

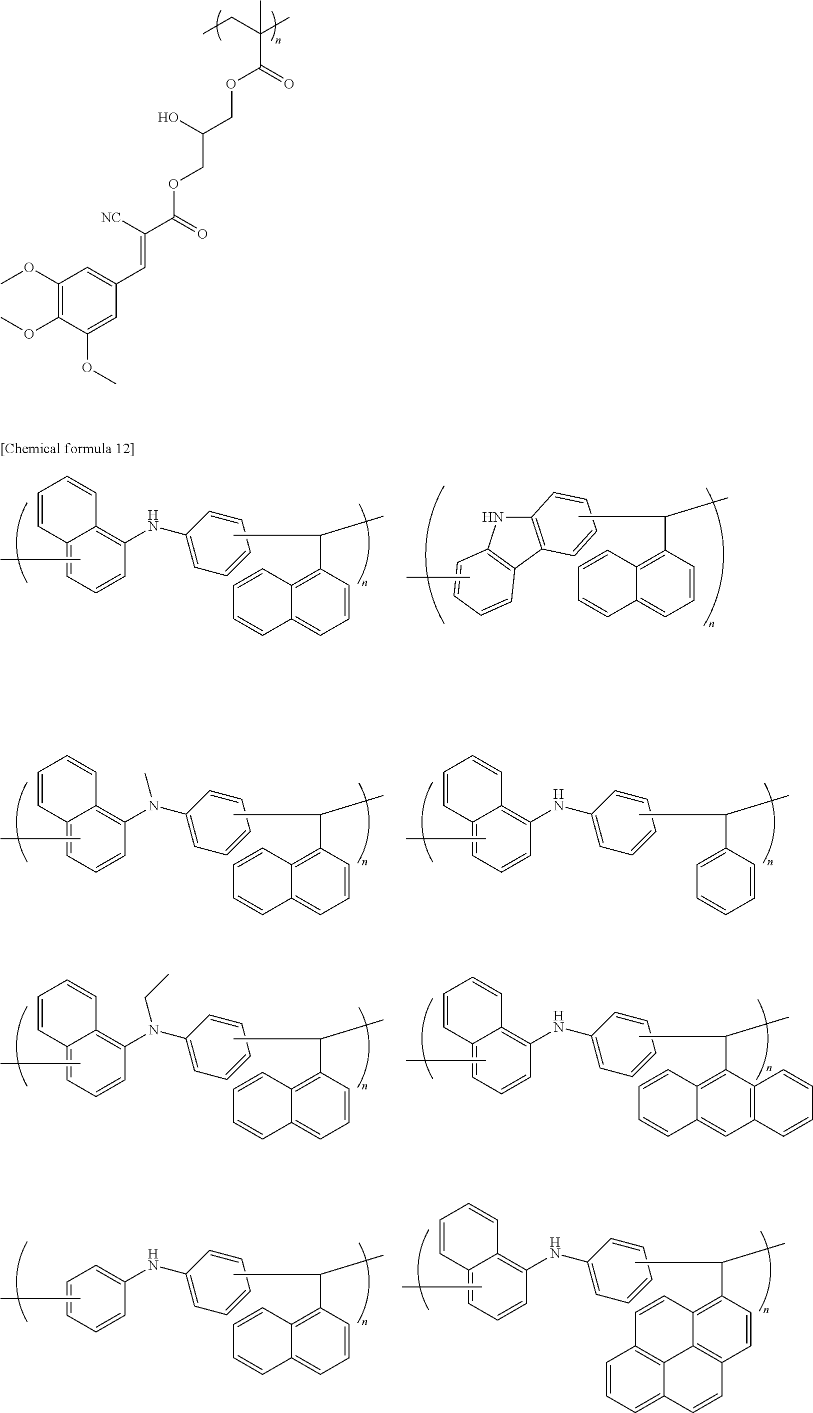

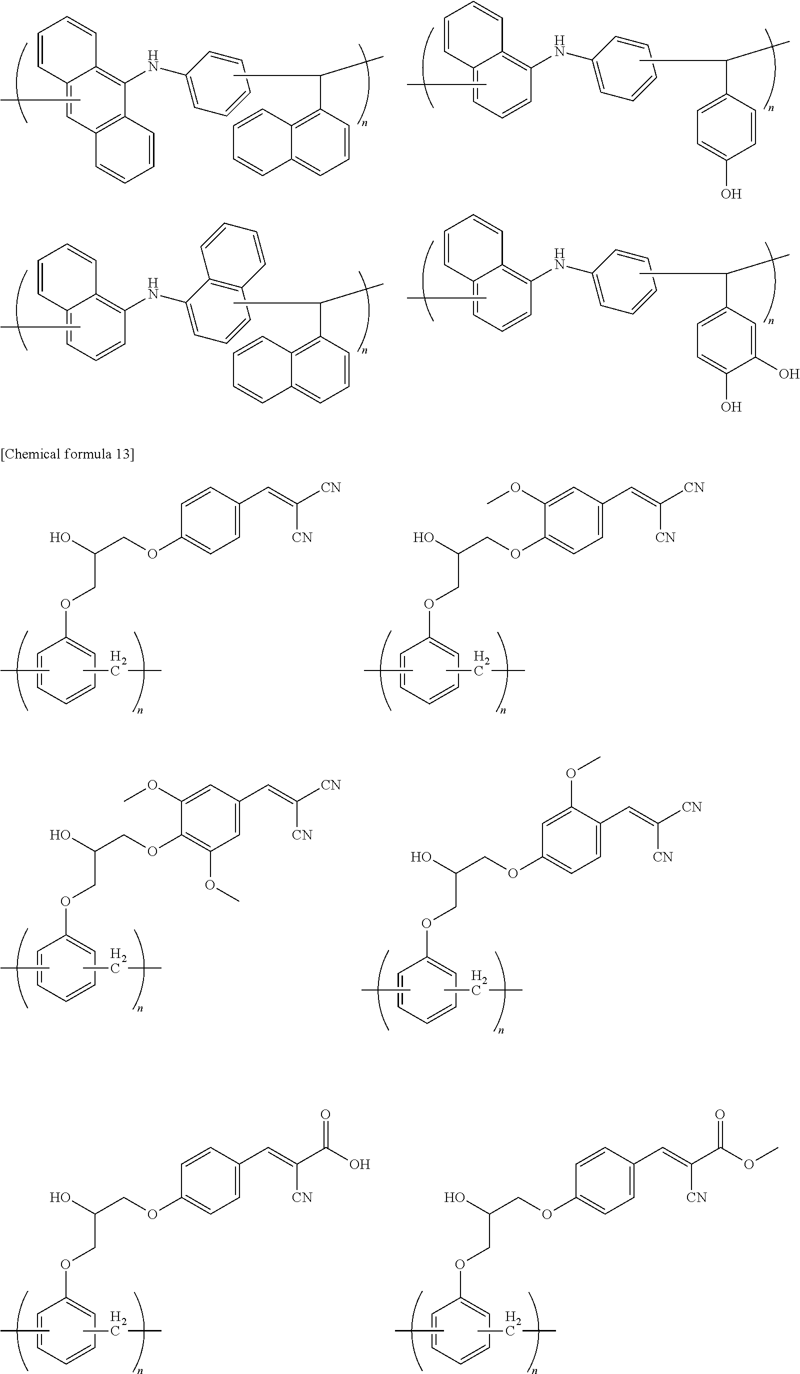

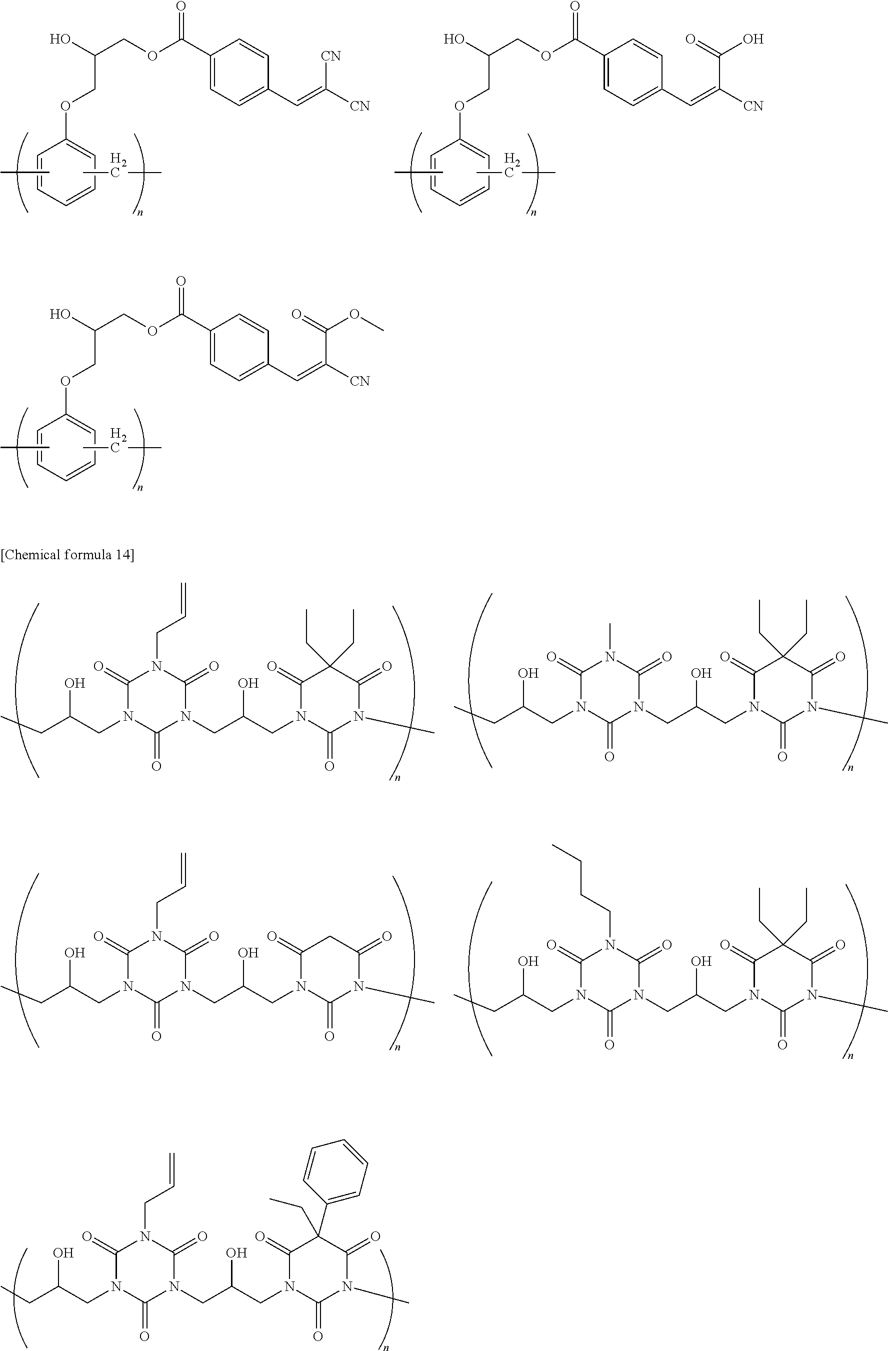

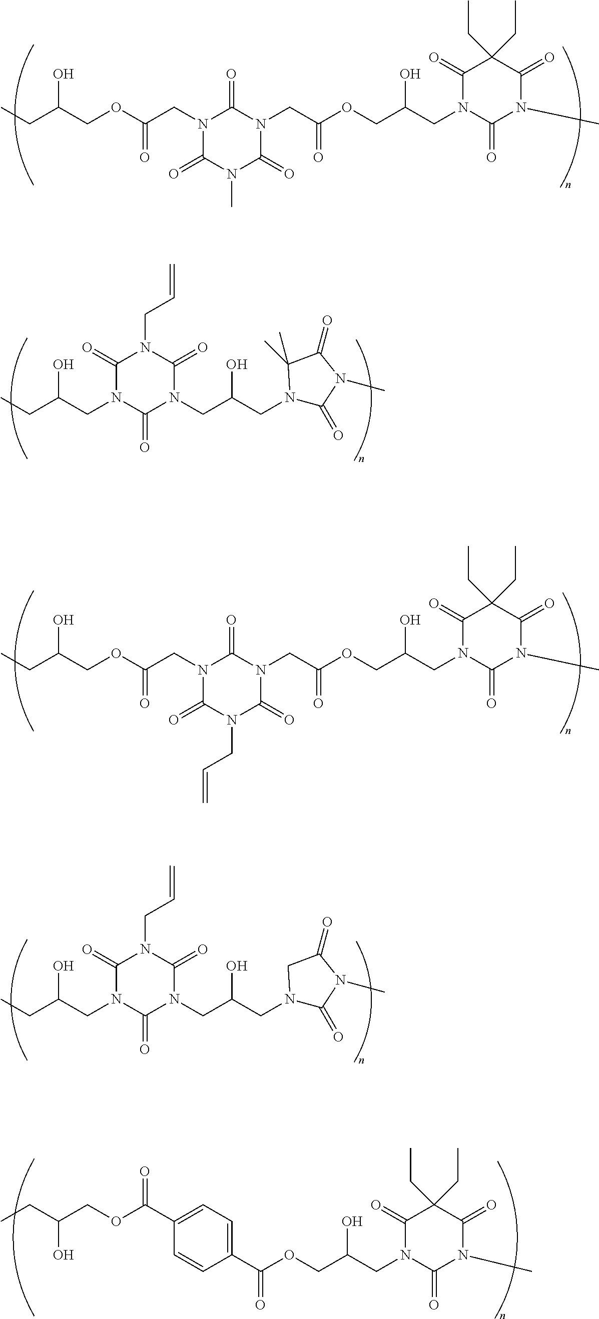

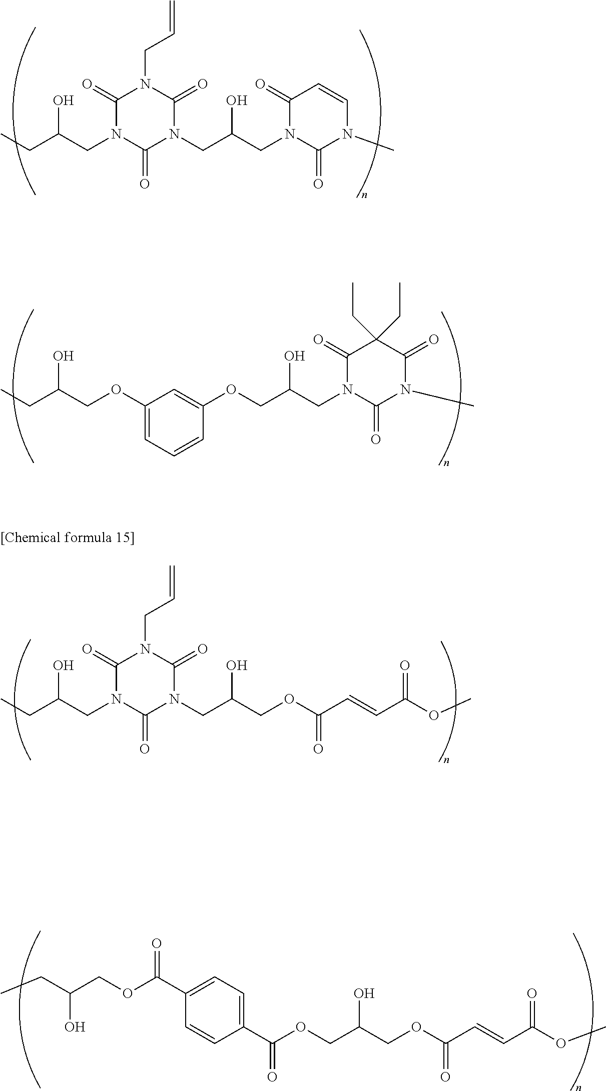

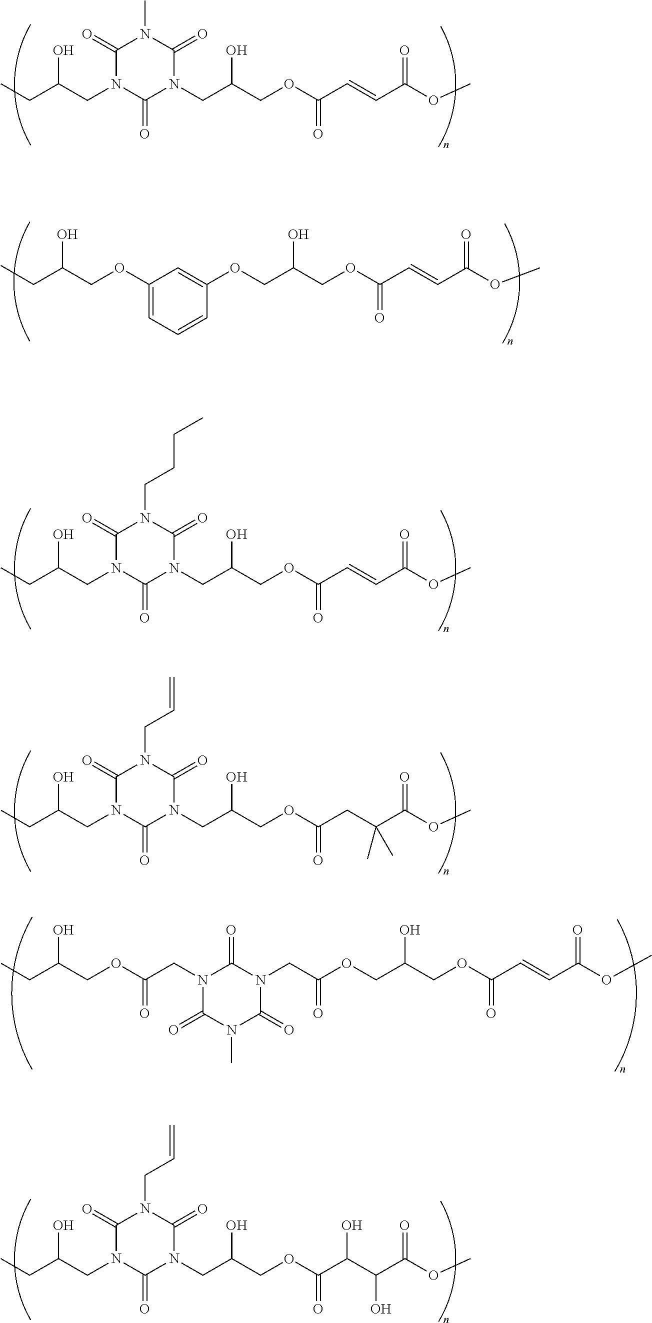

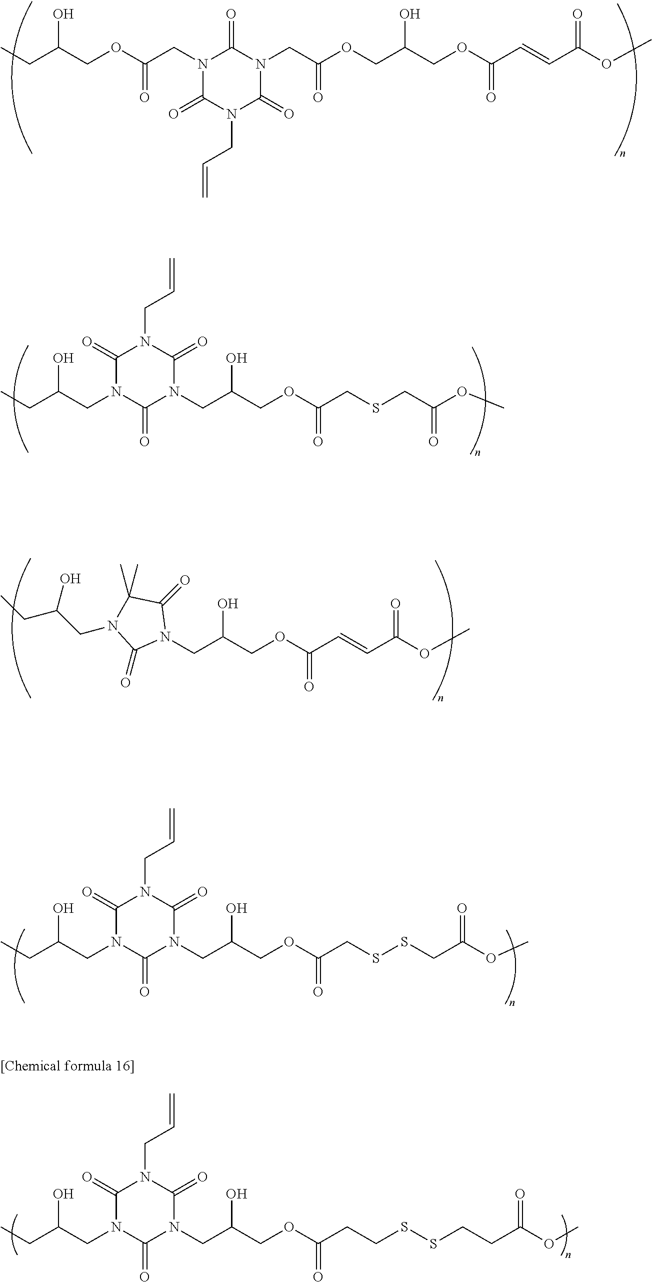

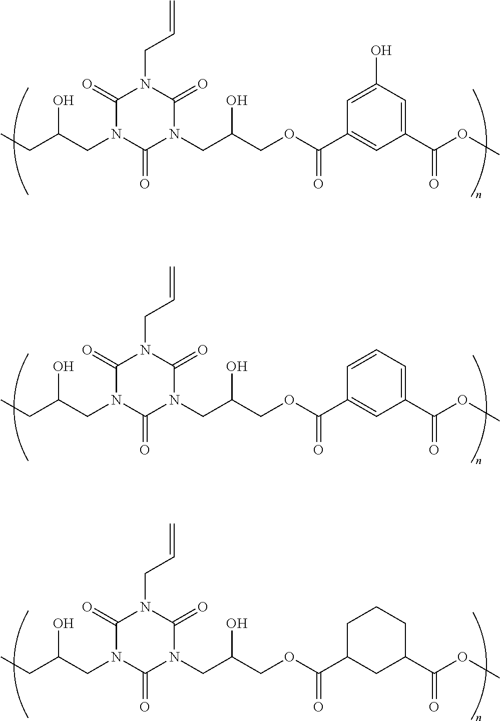

### <Method for Producing a Semiconductor Device, Resist Underlayer Film, and Method for Forming a Resist Pattern>

The method for producing a semiconductor device of the present invention comprises the steps of:

subjecting a substrate having a metal on a surface thereof to oxidation treatment to form a metal oxide film on the surface of the substrate;

applying a resist onto the metal oxide film and baking the applied resist to form a resist film;

exposing the semiconductor substrate covered with the metal oxide film and the resist; and

subjecting the exposed resist film to development and patterning.

The method for producing a semiconductor device of the present invention may comprise the steps of:

applying a resist underlayer film-forming composition to a substrate having a metal on a surface thereof, and then heating the applied composition in the presence of oxygen to form a stacked film having a resist underlayer film present on a metal oxide film;

applying a resist onto the resist underlayer film and baking the applied resist to form a resist film:

exposing the semiconductor substrate covered with the resist underlayer film and the resist; and

subjecting the exposed resist film to development and patterning.

### [Substrate]

In the present invention, the substrate (semiconductor substrate) used in producing a semiconductor device includes, for example, a silicon wafer substrate, a silicon/silicon dioxide coated substrate, a silicon nitride substrate, a glass substrate, an ITO substrate, a polyimide substrate, and a low permittivity material (low-k material) coated substrate.

Recently, in the field of three-dimensional mounting in a semiconductor production process, for the purpose of shortening the wiring length between semiconductor chips to achieve a fast response and save the power, the application of an FOWLP process is starting. In an RDL (redistribution layer) step for forming wiring between semiconductor chips, copper (Cu) is used as a wiring member, and, as the copper wiring is miniaturizing, there is a need to apply an antireflection film (resist underlayer film-forming composition).

### [Resist Underlayer Film and Method for Producing a Semiconductor Device]

The resist underlayer film and method for producing a semiconductor device of the present invention are described below.

The known resist underlayer film-forming composition in the present invention is applied onto the above-mentioned substrate used in producing a semiconductor device (for example, a substrate having copper on the surface thereof) by an appropriate application method, such as a spinner or a coater, and then baked to form a resist underlayer film.

The resist underlayer film in the present invention usually contains a compound or polymer for adjusting the refractive index for antireflection, obtaining a light absorption or achieving adhesion to the materials contained in the resist, as well as an acid generator, a crosslinking agent, and a solvent. The conditions for baking are appropriately selected from those at a baking temperature of 80 to 400° C. for a baking time of 0.3 to 60 minutes. Preferred conditions for baking are those at a baking temperature of 150 to 350° C. for a baking time of 0.5 to 2 minutes. The thickness of the formed resist underlayer film is, for example, within the range of 1 to 1,000 nm, or 2 to 500 nm, or 3 to 400 nm, or 5 to 300 nm, or 5 to 200 nm, or 5 to 100 nm, or 5 to 80 nm, or 5 to 50 nm, or 5 to 30 nm, or 5 to 20 nm.

Further, an inorganic resist underlayer film (hard mask) may be formed on the organic resist underlayer film in the present invention. For example, an inorganic resist underlayer film may be formed from the silicon-containing resist underlayer film (inorganic resist underlayer film) forming composition described in WO 2009/104552A1 by a spin coating method, or a Si inorganic material film may be formed by, for example, a CVD method.

Then, a resist film, for example, a layer of a photoresist is formed on the resist underlayer film. The layer of photoresist may be formed by a known method for removing the solvent from the applied film comprising a resist underlayer film-forming composition, namely, by applying a photoresist composition solution onto the resist underlayer film and baking the applied composition. The thickness of the photoresist is, for example, within the range of 50 to 10,000 nm, or 100 to 4,000 nm.

With respect to the photoresist formed on the resist underlayer film, there is no particular limitation as long as it is sensitive to a light used in the exposure. Any of a negative photoresist and a positive photoresist may be used. They include, for example, a positive photoresist comprising a novolak resin and 1,2-naphthoquinonediazidosulfonate, a chemical amplification photoresist comprising a binder having a group which is decomposed due to an acid to increase the alkali solubility, and a photo-acid generator, a chemical amplification photoresist comprising a low-molecular weight compound which is decomposed due to an acid to increase the alkali solubility of the photoresist, an alkali-soluble binder, and a photo-acid generator, and a chemical amplification photoresist comprising a binder having a group which is decomposed due to an acid to increase the alkali solubility, a low-molecular weight compound which is decomposed due to an acid to increase the alkali solubility of the photoresist, and a photo-acid generator. For example, they include trade name: APEX-E, manufactured by Shipley Company, Inc., trade name: PAR710, manufactured by Sumitomo Chemical Co., Ltd., and trade name: SEPR430, manufactured by Shin-Etsu Chemical Co., Ltd. Further, there can be mentioned fluorine atom-containing polymer photoresists described in, for example, Proc. SPIE, Vol. 3999, 330-334 (2000), Proc. SPIE, Vol. 3999, 357-364 (2000), and Proc. SPIE, Vol. 3999, 365-374 (2000).

Next, a resist pattern is formed by irradiation with a light or electron beam and development. Exposure through a predetermined mask is first conducted. In the exposure, for example, a near ultraviolet light, a far ultraviolet light, or an extreme ultraviolet light (e.g., EUV (wavelength: 13.5 nm)) is used. Specifically, for example, an i-line (wavelength: 365 nm), a KrF excimer laser (wavelength: 248 nm), an ArF excimer laser (wavelength: 193 nm), or an F₂ excimer laser (wavelength: 157 nm) may be used. Of these, an i-line (wavelength: 365 nm) is preferred. After the exposure, if necessary, post exposure bake may be conducted. The post exposure bake may be performed under conditions appropriately selected from those at a heating temperature of 70 to 150° C. for a heating time of 0.3 to 10 minutes.

Further, in the present invention, as a resist, instead of the photoresist, a resist for electron beam lithography may be used. Any of a negative electron beam resist and a positive electron beam resist may be used. They include, for example, a chemical amplification resist comprising an acid generator and a binder having a group which is decomposed due to an acid to change the alkali solubility, a chemical amplification resist comprising an alkali-soluble binder, an acid generator, and a low-molecular weight compound which is decomposed due to an acid to change the alkali solubility of the resist, a chemical amplification resist comprising an acid generator, a binder having a group which is decomposed due to an acid to change the alkali solubility, and a low-molecular weight compound which is decomposed due to an acid to change the alkali solubility of the resist, a non-chemical amplification resist comprising a binder having a group which is decomposed due to an electron beam to change the alkali solubility, and a non-chemical amplification resist comprising a binder having a site which suffers breakage due to an electron beam to change the alkali solubility. Also when using the above electron beam resist, a resist pattern may be similarly formed as in the case where a photoresist is used and an electron beam is used as a source of irradiation.

Then, development using a developer is conducted. In the development, for example, when a positive photoresist is used, the exposed portions of the photoresist are removed, so that a photoresist pattern is formed.

Examples of developers include alkaline aqueous solutions, e.g., aqueous solutions of an alkali metal hydroxide, such as potassium hydroxide or sodium hydroxide, aqueous solutions of a quaternary ammonium hydroxide, such as tetramethylammonium hydroxide, tetraethylammonium hydroxide, or choline, and aqueous solutions of an amine, such as ethanolamine, propylamine, or ethylenediamine. Further, for example, a surfactant can be added to the above developer. The conditions for the development are appropriately selected from those at a temperature of 5 to 50° C. for a time of 10 to 600 seconds.

In the present invention, an organic underlayer film (lower layer) is formed on a substrate, then an inorganic underlayer film (intermediate layer) is formed on the organic film, and the resultant film may be covered with a photoresist (upper layer). By virtue of this, even when a substrate is covered with a photoresist having a smaller thickness for preventing an occurrence of pattern collapse due to a reduced pattern width of the photoresist, appropriate selection of an etching gas enables processing of the substrate. For example, processing of the resist underlayer film may be made by using as an etching gas a fluorine-based gas having an etching rate satisfactorily faster than that for the photoresist, and processing of the substrate may be made by using as an etching gas a fluorine-based gas having an etching rate satisfactorily faster than that for the inorganic underlayer film, and further processing of the substrate may be made by using as an etching gas an oxygen-based gas having an etching rate satisfactorily faster than that for the organic underlayer film.

Subsequently, using the thus formed photoresist pattern as a protective film, the inorganic underlayer film is removed, and then, using a film comprising the patterned photoresist and inorganic underlayer film as a protective film, the organic underlayer film is removed. Finally, using the patterned inorganic underlayer film and organic underlayer film as a protective film, processing of the semiconductor substrate is performed.

First, portions of the inorganic underlayer film, from which the photoresist has been removed, is removed by dry etching so that the semiconductor substrate is allowed to expose. In the dry etching for the inorganic underlayer film, for example, a gas of tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane may be used. In the dry etching for the inorganic underlayer film, a halogen-based gas is preferably used, and a fluorine-based gas is more preferably used. Examples of fluorine-based gases include tetrafluoromethane (CF₄), perfluorocyclobutane (C₄F₈), perfluoropropane (C₃F₈), trifluoromethane, and difluoromethane (CH₂F₂).

Then, using a film comprising the patterned photoresist and inorganic underlayer film as a protective film, the organic underlayer film is removed.

The inorganic underlayer film containing silicon atoms in a large amount is unlikely to be removed by dry etching using an oxygen-based gas, and therefore the organic underlayer film is frequently removed by dry etching using an oxygen-based gas.

Finally, processing of the semiconductor substrate is conducted. The processing of the semiconductor substrate is preferably conducted by dry etching using a fluorine-based gas.

Examples of fluorine-based gases include tetrafluoromethane (CF₄), perfluorocyclobutane (C₄F₈), perfluoropropane (C₃F₈), trifluoromethane, and difluoromethane (CH₂F₂).

Further, before forming the photoresist, an organic antireflection film may be formed on the resist underlayer film as an upper layer. With respect to the antireflection film composition used in forming the antireflection film, there is no particular limitation, and an antireflection film composition may be arbitrarily selected from those which have been commonly used in a lithography process, and an antireflection film may be formed by a method commonly used, for example, by applying the composition using a spinner or a coater and baking the applied composition.

The resist underlayer film formed from the resist underlayer film-forming composition may have an absorption with respect to the light used in a lithography process depending on the wavelength of the light. In such a case, the resist underlayer film may function as an antireflection film having an effect of preventing a light reflected from the substrate. Further, the resist underlayer film formed from the resist underlayer film-forming composition in the present invention may function as a hard mask. The resist underlayer film in the present invention may also be used as, for example, a layer for preventing an interaction between a substrate and a photoresist, a layer having a function for preventing an adverse effect on a substrate by the material used in a photoresist or by a substance formed during the exposure for the photoresist, a layer having a function for preventing a substance generated from a substrate upon heating or baking from diffusing into a photoresist as an upper layer, and a barrier layer for reducing the photoresist layer poisoning effect of a semiconductor substrate dielectric layer.

Further, the resist underlayer film formed from the resist underlayer film-forming composition is applied to a substrate used in a dual-damascene process having via holes formed, and can be used as an encapsulation material capable of completely filling holes. Furthermore, the resist underlayer film can also be used as a planarization material for flattening the uneven surface of a semiconductor substrate.

Meanwhile, for the purpose of simplifying the steps for process, reducing a damage of the substrate, or reducing the cost, instead of removal of the film by dry etching, a method for removal of the film by wet etching using a chemical liquid is studied. A resist underlayer film formed from a conventional resist underlayer film-forming composition, however, needs to be formed as a cured film having a solvent resistance in order to suppress the mixing of the film and the resist being applied. Further, in patterning the resist, a developer for resolving the resist must be used, and the resistance to the developer is indispensable to the cured film. In the method for producing a substrate having a resist pattern of the present invention, the resist underlayer film may be a resist underlayer film that can be etched (removed) by a wet etching liquid.

The wet etching liquid preferably contains, for example, an organic solvent, and may contain an acidic compound or a basic compound. Examples of organic solvents include dimethyl sulfoxide, dimethylformamide, dimethylacetamide, N-methylpyrrolidone, N-ethylpyrrolidone, ethylene glycol, propylene glycol, and diethylene glycol dimethyl ether. Examples of acidic compounds include inorganic acids and organic acids, and examples of inorganic acids include hydrochloric acid, sulfuric acid, nitric acid, and phosphoric acid, and examples of organic acids include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, acetic acid, propionic acid, trifluoroacetic acid, citric acid, benzoic acid, hydroxybenzoic acid, and naphthalenecarboxylic acid. Examples of basic compounds include inorganic bases and organic bases, and examples of inorganic bases include alkali metal hydroxides, such as sodium hydroxide and potassium hydroxide; quaternary ammonium hydroxides, such as tetramethylammonium hydroxide, tetraethylammonium hydroxide, and choline; and amines, such as ethanolamine, propylamine, diethylaminoethanol, and ethylenediamine. Further, in the wet etching liquid, a single type of organic solvent may be used, or two or more types of organic solvents may be used in combination. A single type of acidic compound or basic compound may be used, or two or more types of acidic compounds or basic compounds may be used in combination. The amount of the acidic compound or basic compound incorporated is within the range of 0.01 to 20% by weight, preferably 0.1 to 5% by weight, especially preferably 0.2 to 1% by weight, based on the weight of the wet etching liquid. The wet etching liquid is preferably an organic solvent containing a basic compound, especially preferably a mixture containing dimethyl sulfoxide and tetramethylammonium hydroxide.

Recently, in the field of three-dimensional mounting in a semiconductor production process, the application of an FOWLP (Fan-Out Wafer Level Package) process is starting, and, in an RDL (redistribution layer) step for forming a copper wiring, a resist underlayer film may be applied.

In a representative RDL step, the application of the resist underlayer film is described below, but is not limited to the following description. A photosensitive insulating film is first formed on a semiconductor chip, and then subjected to irradiation with a light (exposure) and development to perform patterning, so that a semiconductor chip electrode portion is opened. Subsequently, a copper seed layer for forming copper wiring as a wiring member in the plating step is formed by sputtering. Further, a resist underlayer film and a photoresist layer are successively formed, and then subjected to irradiation with a light and development, performing patterning of the resist. The unnecessary resist underlayer film is removed by dry etching, and copper is electroplated on the copper seed layer in the exposed resist pattern, forming copper wiring as a first wiring layer. Further, the unnecessary resist, resist underlayer film, and copper seed layer are removed by dry etching, wet etching, or both. The formed copper wiring layer is further covered with an insulating film, and then a copper seed layer, a resist underlayer film, and a resist are formed in this order, and patterning of the resist, removal of the resist underlayer film, and copper plating are preformed, forming a second copper wiring layer. The above steps are repeated to form an intended copper wiring, and then a bump for taking an electrode out is formed.

The resist underlayer film described in the present invention may be removed by wet etching, and therefore may be especially preferably used as a resist underlayer film in the RDL step from the viewpoint of simplifying the steps for process or reducing a damage of the substrate processed.

In addition, the meanings of the terms used in the above description are as defined above.

### <Method for Reducing Standing Waves of a Resist Pattern>

The method for reducing standing waves of a resist pattern of the present invention comprises the steps of:

subjecting a substrate, preferably semiconductor substrate, having a metal on a surface thereof to oxidation treatment to form a metal oxide film on the surface of the substrate;

applying a resist onto the metal oxide film and baking the applied resist to form a resist film;

exposing the substrate, preferably a semiconductor substrate, covered with the metal oxide film and the resist; and

subjecting the exposed resist film to development and patterning.

The method for reducing standing waves of a resist pattern of the present invention may comprise the steps of:

applying a resist underlayer film-forming composition to a substrate, preferably semiconductor substrate, having a metal on the surface thereof, and then heating the applied composition in the presence of oxygen to form a stacked film having a resist underlayer film present on a metal oxide film;

applying a resist onto the resist underlayer film and baking the applied resist to form a resist film;

exposing the substrate, preferably a semiconductor substrate, covered with the resist underlayer film and the resist; and

subjecting the exposed resist film to development and patterning.

The meanings of the terms used in the above description are as defined above.

### EXAMPLES

Hereinbelow, the present invention will be described in more detail with reference to the following Examples, which should not be construed as limiting the scope of the present invention.

### Preparation Example 1

### [Preparation of a Resist Underlayer Film-Forming Composition]

To 3.63 g of the solution of the reaction product (solids content: 16.78% by weight) produced by the method in accordance with Synthesis Example 2 of WO 2020/255984 were added 0.12 g of tetramethoxymethylglycoluril (trade name: POWDER LINK [registered trademark] 1174, manufactured by Nihon Cytec Industries Inc.) as a crosslinking agent, 0.006 g of pyridinium p-toluenesulfonate as a crosslinking catalyst, 0.01 g of MEGAFACE R-30N (trade name, manufactured by DIC Corporation), 134.37 g of propylene glycol monomethyl ether, and 14.93 g of propylene glycol monomethyl ether acetate, to prepare a resist underlayer film-forming composition for lithography in the form of a solution. The above-mentioned reaction product contains a structure represented by the following formula (A-2).

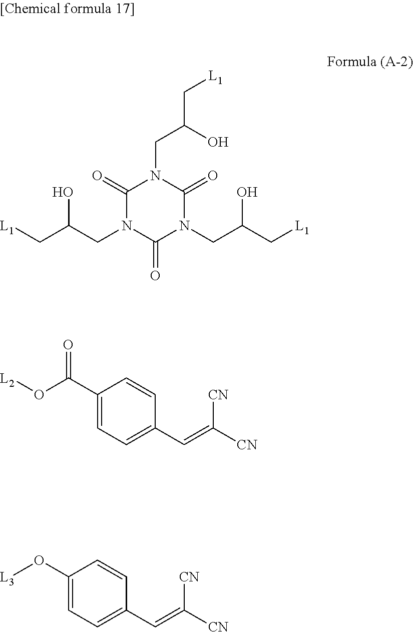

Wherein L₁ represents a bonding site to L₂ and L₃.

### [Evaluation of the Optical Coefficient of a Copper Oxide Film]

Evaluation of the optical coefficient was made as follows. A copper substrate was baked on a hotplate at 150° C. for 10 to 60 minutes to form a copper oxide film on a surface layer of the copper substrate. With respect to the obtained copper oxide film, using a spectroscopic ellipsometer (M-2000D, manufactured by J. A. Woollam Co., Inc.), an n value (refractive index) and a k value (attenuation coefficient) were measured at a wavelength of 365 nm (i-line wavelength). The results are shown in Table 1.

TABLE 1

| Baking conditions | n/k (365 nm) |
|---|---|
| 150° C., 10 min. | 2.74/1.32 |
| 150° C., 30 min. | 2.74/1.32 |
| 150° C., 60 min. | 2.71/1.34 |

As apparent from the above results, the copper oxide film obtained by the baking treatment on a hotplate had an appropriate n value and k value at 365 nm, and thus had an antireflection function that could suppress reflection (standing wave) from the substrate, a cause of an unfavorable resist pattern, in a lithography process using radiation, such as an i-line. Therefore, the copper oxide film is advantageously used as a resist underlayer film.

### [Evaluation of the Optical Coefficient in Preparation Example 1]

Evaluation of the optical coefficient was made as follows. The resist underlayer film-forming composition for lithography prepared in Preparation Example 1 was applied onto a silicon wafer by a spin coater so as to have a thickness of about 50 nm, and baked on a hotplate at 200° C. for 90 seconds. With respect to the obtained resist underlayer film, using a spectroscopic ellipsometer (VUV-VASE, manufactured by J. A. Woollam Co., Inc.), an n value (refractive index) and a k value (attenuation coefficient) were measured at a wavelength of 365 nm (i-line wavelength). The results are shown in Table 2.

TABLE 2

| | n/k (365 nm) |
|---|---|
| Preparation Example 1 | 1.82/0.22 |

As apparent from the above results, the resist underlayer film-forming composition obtained in Preparation Example 1 had an appropriate n value and k value at 365 nm, and thus had an antireflection function that could suppress reflection (standing wave) from the substrate, a cause of an unfavorable resist pattern, in a lithography process using radiation, such as an i-line. Therefore, the film obtained from the composition is advantageously used as a resist underlayer film.

### [Evaluation of the Resist Pattern Form]

### Example 1

A copper substrate having a diameter of 8 inches was baked on a hotplate at 150° C. for 30 minutes to form a copper oxide film (thickness: about 20 nm) on the surface layer of the copper substrate. Then, a commercially available positive resist for i-line exposure was applied to the copper oxide film by a spin coater so as to have a thickness of about 2 μm, and prebaked on a hotplate at 90° C. for 3 minutes to form a photoresist stacked material. Then, the photoresist stacked material was subjected to i-line exposure using a stepper (NSR-2205i12D, manufactured by Nikon Corporation) through a pattern mask for resolution measurement. After the exposure, the resultant stacked material was post-baked at 90° C. for 90 seconds, and subjected to development using a 2.38% aqueous solution of tetramethylammonium hydroxide (TMAH) (product name: NMD-3, manufactured by Tokyo Ohka Kogyo Co., Ltd.), which is a resist developer, obtaining a 0.8 μm resist pattern having a 1:1 line-and-space. Then, the cross-sectional form of the obtained resist pattern was observed by means of a scanning electron microscope, and waviness of the resist pattern form due to the standing waves was evaluated.

### Example 2

The resist underlayer film-forming composition for lithography prepared in Preparation Example 1 was applied onto a copper substrate having a diameter of 8 inches by a spin coater so as to make a layer having a thickness of about 10 nm, and baked on a hotplate at 200° C. for 90 seconds, to form simultaneously a copper oxide film (thickness: about 10 nm) on a surface of the copper substrate and a layer of the resist underlayer film-forming composition for lithography on the copper oxide film. Then, an ordinary i-line resist was applied thereon by a spin coater so as to make a film having a thickness of about 2 μm, and prebaked on a hotplate at 90° C. for 3 minutes, to form a photoresist stacked material. Then, the photoresist stacked material was subjected to i-line exposure using a stepper (NSR-2205i12D, manufactured by Nikon Corporation) through a pattern mask for resolution measurement. After the exposure, the resultant stacked material was post-baked at 90° C. for 90 seconds, and subjected to development using a 2.38% aqueous solution of tetramethylammonium hydroxide (TMAH) (product name: NMD-3, manufactured by Tokyo Ohka Kogyo Co., Ltd.), a resist developer, obtaining a 0.8 μm resist pattern having a 1:1 line-and-space. Then, the cross-sectional form of the obtained resist pattern was observed by means of a scanning electron microscope, and waviness of the resist pattern form due to the standing waves was evaluated.

### Example 3

A copper substrate having a diameter of 8 inches was baked on a hotplate at 150° C. for 30 minutes to form a copper oxide film (thickness: about 20 nm) on a surface of the copper substrate.

Then, the resist underlayer film-forming composition for lithography prepared in Preparation Example 1 was applied to the copper oxide film by a spin coater so as to make a layer having a thickness of about 10 nm, and baked on a hotplate at 200° C. for 90 seconds, to form a layer of the resist underlayer film-forming composition for lithography on the copper oxide film. Then, an ordinary i-line resist was applied to the composition by a spin coater so as to make a film having a thickness of about 2 μm, and prebaked on a hotplate at 90° C. for 3 minutes, to form a photoresist stacked material. Then, the photoresist stacked material was subjected to i-line exposure using a stepper (NSR-2205i12D, manufactured by Nikon Corporation) through a pattern mask for resolution measurement. After the exposure, the resultant stacked material was post-baked at 90° C. for 90 seconds, and subjected to development using a 2.38% aqueous solution of tetramethylammonium hydroxide (TMAH) (product name: NMD-3, manufactured by Tokyo Ohka Kogyo Co., Ltd.), a resist developer, obtaining a 0.8 μm resist pattern having a 1:1 line-and-space. Then, the cross-sectional form of the obtained resist pattern was observed by means of a scanning electron microscope, and waviness of the resist pattern form due to the standing waves was evaluated.

### Comparative Example 1

A commercially available positive resist for i-line exposure was applied onto a copper substrate having a diameter of 8 inches by a spin coater so as to make a film having a thickness of about 2 μm, and prebaked on a hotplate at 90° C. for 3 minutes to form a photoresist stacked material. Then, the photoresist stacked material was subjected to i-line exposure using a stepper (NSR-2205i12D, manufactured by Nikon Corporation) through a pattern mask for resolution measurement. After the exposure, the resultant stacked material was post-baked at 90° C. for 90 seconds, and subjected to development using a 2.38% aqueous solution of tetramethylammonium hydroxide (TMAH) (product name: NMD-3, manufactured by Tokyo Ohka Kogyo Co., Ltd.), a resist developer, obtaining a 0.8 μm resist pattern having a 1:1 line-and-space. Then, the cross-sectional form of the obtained resist pattern was observed by means of a scanning electron microscope, and waviness of the resist pattern form due to the standing waves was evaluated.

Criteria for evaluation of the resist pattern form are as follows. With respect to the waviness of the resist pattern form due to the standing waves in Examples 1 to 3 and Comparative Example 1, the rating “x” indicates that the waviness is large, as compared to that in Comparative Example 1, and the rating “∘” indicates that the waviness is small, as compared to that in Comparative Example 1, and the results are shown in Table 3 below. The thickness of the copper oxide film was measured by observing the cross-section of the substrate using a scanning electron microscope.

TABLE 3
Results of evaluation of resist pattern form

| | | Resist underlayer | Suppression of |
|---|---|---|---|
| | Inorganic film | film | standing wave |
| Example 1 | Copper oxide | — | ◯ |
| | About 20 nm | | |
| Example 2 | Copper oxide | About 10 nm | ◯ |
| | About 10 nm | | |
| Example 3 | Copper oxide | About 10 nm | ◯ |
| | About 20 nm | | |
| Comparative | — | — | — |
| Example 1 | | | |

As apparent from the above results, in Examples 1 to 3, a resist pattern form having a smaller waviness due to the standing waves, as compared to the waviness in Comparative Example 1, was obtained. That is, by using a copper oxide film, or by using a copper oxide film and a resist underlayer film combinedly, reflection (standing waves) from the copper substrate caused at the time of exposure in the lithography could be reduced, making it possible to suppress occurrence of an unfavorable phenomenon of waves of the resist pattern form after the development.

### INDUSTRIAL APPLICABILITY

By the present invention, in a lithography process for the production of a semiconductor device, the exposure reflectance from a substrate can be reduced, so that standing waves of a resist pattern (problem due to reflection) is reduced, making it possible to obtain a resist pattern having an excellent rectangular form on the substrate.

1. A method for producing a substrate having a resist pattern, comprising the steps of:
subjecting a substrate having a metal on a surface thereof to oxidation treatment to form a metal oxide film on the surface of the substrate;
applying a resist onto the metal oxide film and baking the applied resist to form a resist film;
exposing the substrate covered with the metal oxide film and the resist; and
subjecting the exposed resist film to development and patterning.

2. A method for producing a substrate having a resist pattern, comprising the steps of:
applying a resist underlayer film-forming composition to a substrate having a metal on a surface thereof, and then heating the applied composition in the presence of oxygen to form a stacked film having a resist underlayer film present on a metal oxide film;
applying a resist onto the resist underlayer film and baking the applied resist to form a resist film;
exposing the substrate covered with the resist underlayer film and the resist; and
subjecting the exposed resist film to development and patterning.

3. The method for producing a substrate having a resist pattern according to claim 1, wherein the resist pattern has reduced standing waves.

4. The method for producing a substrate having a resist pattern according to claim 1, wherein the oxidation treatment is selected from a heating treatment in the presence of oxygen, an oxygen plasma treatment, an ozone treatment, a hydrogen peroxide treatment, and an oxidizing agent-containing alkaline chemical liquid treatment.

5. The method for producing a substrate having a resist pattern according to claim 1, wherein the metal comprises copper.

6. The method for producing a substrate having a resist pattern according to claim 2, wherein the resist underlayer film comprises a heterocyclic compound.

7. The method for producing a substrate having a resist pattern according to claim 2, wherein the resist underlayer film comprises a compound represented by the following formula (I): 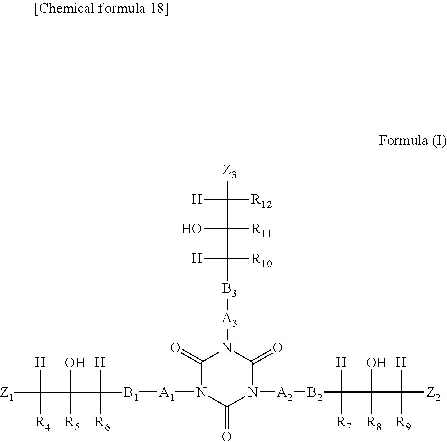
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 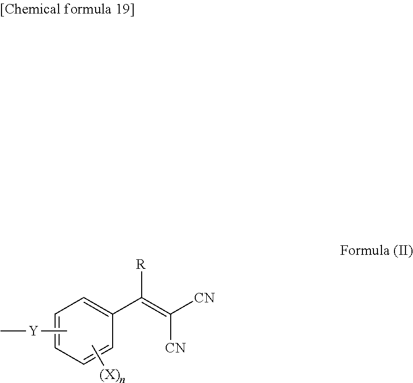
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

8. A method for producing a semiconductor device, comprising the steps of:
subjecting a semiconductor substrate having a metal on a surface thereof to oxidation treatment to form a metal oxide film on the surface of the substrate;
applying a resist onto the metal oxide film and baking the applied resist to form a resist film;
exposing the semiconductor substrate covered with the metal oxide film and the resist; and
subjecting the exposed resist film to development and patterning.

9. A method for producing a semiconductor device, comprising the steps of:
applying a resist underlayer film-forming composition to a semiconductor substrate having a metal on a surface thereof, and then heating the applied composition in the presence of oxygen to form a stacked film having a resist underlayer film present on a metal oxide film;
applying a resist onto the resist underlayer film and baking the applied resist to form a resist film;
exposing the semiconductor substrate covered with the resist underlayer film and the resist; and
subjecting the exposed resist film to development and patterning.

10. A method for reducing standing waves of a resist pattern, comprising the steps of:
subjecting a substrate or semiconductor substrate having a metal on a surface thereof to oxidation treatment to form a metal oxide film on the surface of the substrate;
applying a resist onto the metal oxide film and baking the applied resist to form a resist film;
exposing the substrate or semiconductor substrate covered with the metal oxide film and the resist; and
subjecting the exposed resist film to development and patterning.

11. A method for reducing standing waves of a resist pattern, comprising the steps of:
applying a resist underlayer film-forming composition to a substrate or semiconductor substrate having a metal on a surface thereof, and then heating the applied composition in the presence of oxygen to form a stacked film having a resist underlayer film present on a metal oxide film;
applying a resist onto the resist underlayer film and baking the applied resist to form a resist film;
exposing the substrate or semiconductor substrate covered with the resist underlayer film and the resist; and
subjecting the exposed resist film to development and patterning.

12. The method for producing a substrate having a resist pattern according to claim 2, wherein the resist pattern has reduced standing waves.

13. The method for producing a substrate having a resist pattern according to claim 2, wherein the metal comprises copper.

14. The method for producing a substrate having a resist pattern according to claim 3, wherein the resist underlayer film comprises a compound represented by the following formula (I): 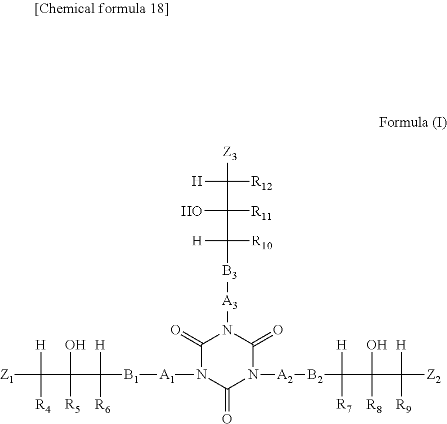
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 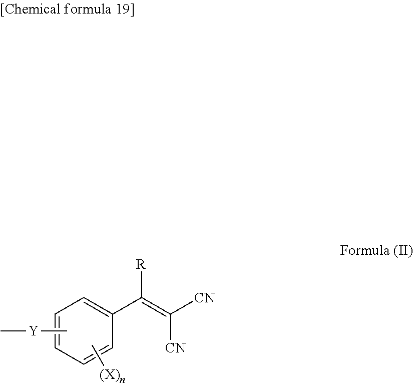
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

15. The method for producing a substrate having a resist pattern according to claim 4, wherein the resist underlayer film comprises a compound represented by the following formula (I): 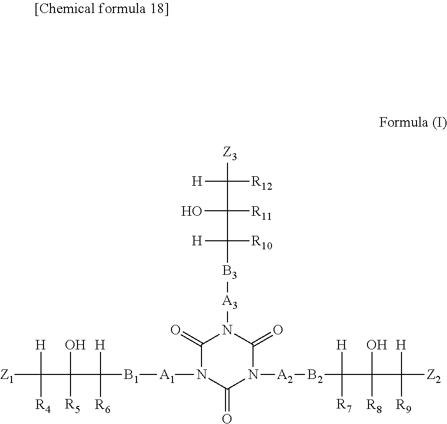
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 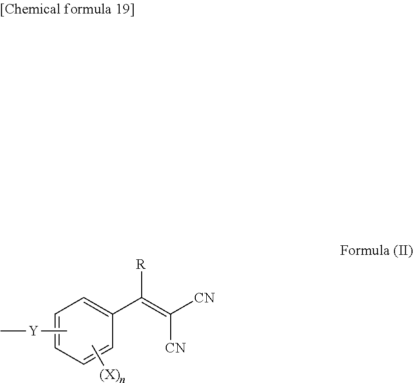
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

16. The method for producing a substrate having a resist pattern according to claim 5, wherein the resist underlayer film comprises a compound represented by the following formula (I): 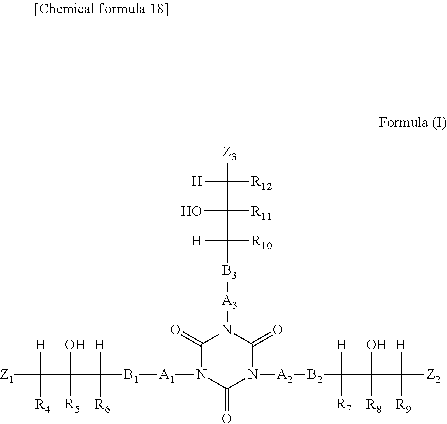
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 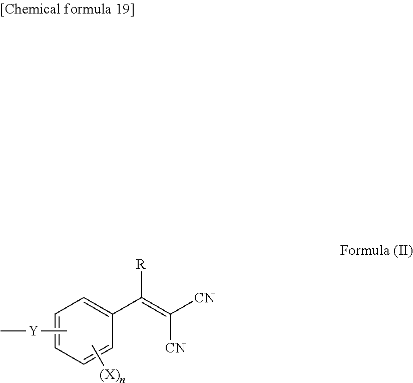
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

17. The method for producing a substrate having a resist pattern according to claim 6, wherein the resist underlayer film comprises a compound represented by the following formula (I): 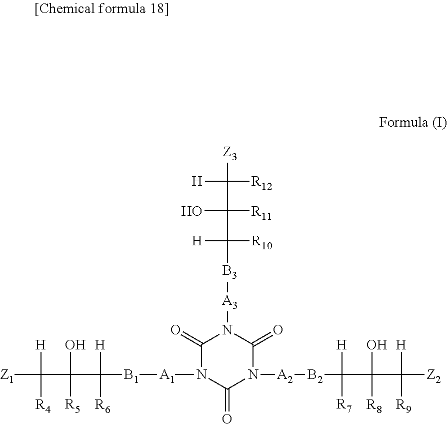
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 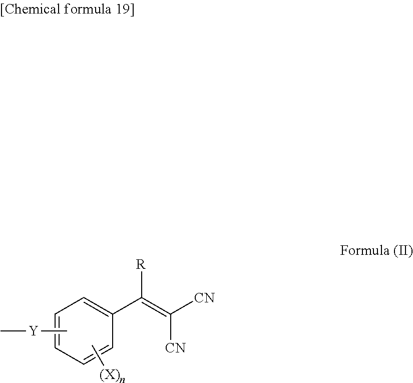
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

18. The method for producing a substrate having a resist pattern according to claim 12, wherein the resist underlayer film comprises a compound represented by the following formula (I): 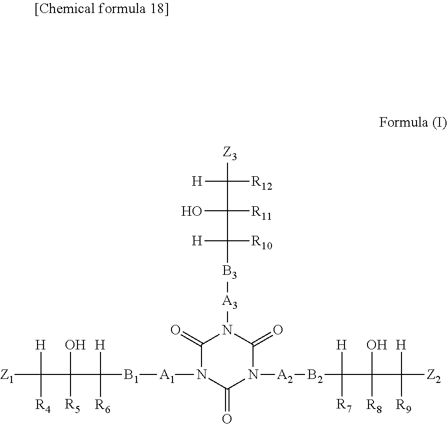
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 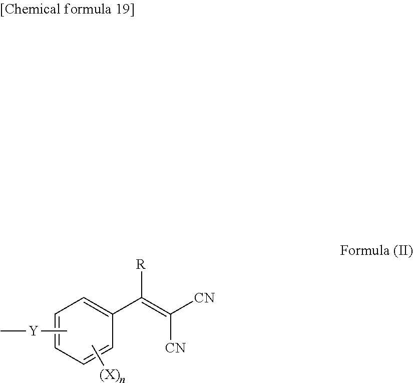
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.

19. The method for producing a substrate having a resist pattern according to claim 13, wherein the resist underlayer film comprises a compound represented by the following formula (I): 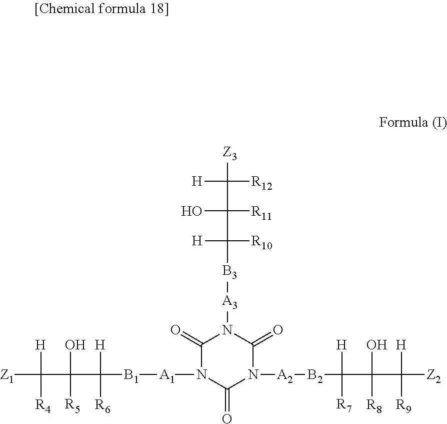
wherein:
each of A₁ to A₃ is independently a direct bond or an optionally substituted alkylene group having 1 to 6 carbon atoms,
each of B₁ to B₃ independently represents a direct bond, an ether linkage, a thioether linkage, or an ester linkage,
each of R₄ to R₁₂ independently represents a hydrogen atom, a methyl group, or an ethyl group, and
Z₁ to Z₃ represent the following formula (II): 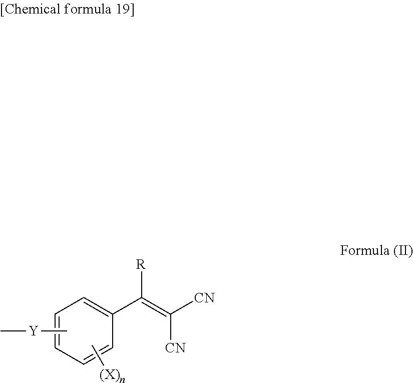
wherein:
each of n quantity of X independently represents an alkyl group, a hydroxy group, an alkoxy group, an alkoxycarbonyl group, a halogen atom, a cyano group, or a nitro group,
R represents a hydrogen atom, an alkyl group, or an arylene group,
Y represents an ether linkage, a thioether linkage, or an ester linkage, and
n represents an integer of 0 to 4.
